(19) United States
(12) Patent Application Publication
(10) Pub. No.: US 2009/0068790 A1
(43) Pub. Date: Mar. 12, 2009

(54) Electrical Interconnect Formed by Pulsed Dispense

(75) Inventors: Terrence Caskey, Santa Cruz, CA (US); Lawrence Douglas Andrews, JR., Los Gatos, CA (US); Simon J.S. McElrea, Scotts Valley, CA (US); Scott McGrath, Scotts Valley, CA (US); Jeffrey S. Leal, Santa Cruz, CA (US)

Correspondence Address: HAYNES BEFFEL & WOLFELD LLP, P O BOX 366, HALF MOON BAY, CA, 94019, US

(73) Assignee: Vertical Circuits, Inc., Scotts Valley, CA (US)

(21) Appl. No.: 12/124,097

(22) Filed: May 20, 2008

Related U.S. Application Data
(60) Provisional application No. 60/981,457, filed on Oct. 19, 2007.
(60) Provisional application No. 60/970,903, filed on Sep. 7, 2007.

(51) Int. Cl. H01L 21/60; H01L 21/44

(52) U.S. Cl. 438/109; 438/618; 257/E21.506; 257/E21.476

(57) ABSTRACT

Methods for depositing interconnect material at a target for electrical interconnection include pulsed dispense of the material. In some embodiments droplets of interconnect material are deposited in a projectile fashion. In some embodiments the droplets are shaped by movement of the deposition tool following a deposition pulse and prior to separation of the droplet mass from the tool.

### CROSS-REFERENCE TO RELATED APPLICATIONS

This application claims priority from U.S. Provisional Application No. 60/981,457, titled “Electrical interconnect formed by dot dispense,” which was filed Oct. 19, 2007; and in part from U.S. Provisional Application No. 60/970,903, titled “Electrically interconnected stacked die assemblies,” which was filed Sep. 7, 2007.

This application is related to U.S. Application Atty Docket No. VCIX 1041-2, titled “Electrically interconnected stacked die assemblies”, which claims priority from U.S. Provisional Application No. 60/970,903 (cited above), and which is being filed on the same date as this application. The above-referenced applications are hereby incorporated herein by reference.

### BACKGROUND

This invention relates to electrical interconnection of integrated circuit chips and, particularly, to interconnection of assemblies including one or more integrated circuit chips.

Some die as provided have die pads along one or more of the die margins, and these may be referred to as peripheral pad die. Other die as provided have die pads arranged in one or two rows near the center of the die, and these may be referred to as center pad die. The die may be “rerouted” to provide a suitable arrangement of interconnect pads at or near one or more of the margins of the die.

Die may be interconnected by forming durable contact of interconnects with selected corresponding pads on the respective die. Or, the die pads may be provided with interconnect terminals, and the die may be interconnected by forming durable contact of interconnects with selected corresponding interconnect terminals on the respective die. An interconnect terminal may include, for example, a tab bond or ribbon bond, and may extend from the pad beyond the die edge (so-called “off-die” terminal). Or, an interconnect terminal may constitute a trace of electrically conductive material contacting the pad and running to the die edge, or around the die edge to the die sidewall.

Interconnection of die in a stack, and of stacked die with underlying circuitry, such as a substrate or printed circuit board, presents a number of challenges.

U.S. Pat. No. 7,215,018 and U.S. Pat. No. 7,245,021 describe vertical electrical interconnection of stacked die by applying electrically conductive polymer, or epoxy, filaments or lines to sides of the stack.

### SUMMARY

In various general aspects the invention features methods for electrical interconnection of die in a stack, and of stacked die with a substrate, and assemblies made by the methods. Generally according to the invention an electrical interconnect material is deposited in situ in a pulsed manner; that is, the material is deposited in a pulse or a series of pulses to form an electrically continuous interconnection.

In a general aspect the invention features a method for forming an electrical interconnect between electrical interconnect sites (deposition “targets”), by pulsed dispense of interconnect material, the interconnect material making electrical contact with at least one said electrical interconnect site. The electrical interconnect site may be one of a site on a die, or a site on a support such as a leadframe or a package substrate or a printed circuit board.

In some embodiments the invention features a method for forming an electrical interconnect between vertically adjacent die in a die stack, or between vertically spaced-apart die in a die stack, or between horizontally proximate die or die stacks, or between a die or a die stack and a support such as for example a substrate or a leadframe or a printed circuit board, by depositing a first droplet of an interconnect material at a first target, and depositing a second droplet of an interconnect material on a second target, and contacting the first and second droplets to provide electrical continuity between the first and second targets. In some embodiments the second droplet as deposited contacts the first droplet; in other embodiments the second droplet is allowed to contact the first droplet subsequent to depositing the droplets. In some embodiments a subsequent treatment contacts the second droplet with the first droplet. In some embodiments one of the first and second targets includes an electrical feature, such as an interconnect terminal or an interconnect pad, on a die; in some such embodiments each of the first and second targets includes an electrical feature, such as an interconnect terminal or an interconnect pad, on a die.

In some embodiments the first target includes an electrical feature such as a bond pad on underlying circuitry, such as on a substrate or printed circuit; in some such embodiments the first target includes both an electrical feature, such as an interconnect terminal or interconnect pad, on a die and an electrical feature such as a bond pad on underlying circuitry. In some embodiments one of the first and second targets includes a previously-deposited droplet. In some embodiments the first target includes a transfer surface, onto which the conductive material is deposited in a specified pattern for later transfer to a die stack.

The interconnect material may be a curable material and, depending upon the material and the technique, the interconnect material may be deposited in an uncured or partially cured state, and the material may be partially or additionally cured at an intermediate stage following dispense, and may be fully cured when dispense has been completed. Where the interconnect material is a curable material, it may be electrically conductive as deposited, or as partially or fully cured. A suitable interconnect material may be an electrically conductive polymer. Suitable electrically conductive polymers include polymers filled with conductive material in particle form such as, for example, metal-filled polymers, including, for example metal filled epoxy, metal filled thermosetting polymers, metal filled thermoplastic polymers, or an electrically conductive ink. The conductive particles may range widely in size and shape; they may be for example nanoparticles or larger particles. In some embodiments the conductive material can be a partially-curable polymer; a partial cure may be performed at an earlier stage in the process, and a final cure or post-cure may be performed at a later stage to increase the robustness of the interconnection. In some embodiments the interconnect material provides a mechanical strength (for example, helping to hold the die together in the stack) as well as a reliable electrical interconnection.

In another general aspect the invention features a method for electrically interconnecting a first die to a second die, by providing first and second die each having interconnect sites at or near a die edge, positioning the die in relation to the one another such that corresponding sites to be connected are aligned, and dispensing an interconnect material dropwise (that is, by pulsed dispense of one or more droplets of the interconnect material), such that the interconnect material provides electrical continuity between the corresponding sites. In some embodiments one or more additional die are mounted over the first two die, and interconnected by pulsed deposition to form an electrically interconnected stacked die assembly having any desired number of die. In some embodiments such an interconnected stacked die assembly having two or more die is mounted onto a support such as a substrate or leadframe or printed circuit board, and electrically connected to underlying circuitry in the support.

In some embodiments the die are stacked so that the die edges overlie one another, so that the stack face is generally planar and generally perpendicular to the die front side. In some embodiments successive die in the stack are offset so that the die edges adjacent the interconnect sites present a stairstep configuration. In some embodiments the die in the stack are offset so that the die in the stack present a staggered configuration.

In some embodiments successively interconnected die in the stack are separated by a spacer; in some such embodiments the spacer is a dielectric film such as a die attach film. In embodiments where the die in the stack present a staggered configuration, odd-numbered die in the stack constitute successively interconnected die, and they are separated by even-numbered die; similarly, even-numbered die in the stack also constitute successively interconnected die, and they are separated by odd-numbered die.

In another general aspect the invention features a method for electrically interconnecting a die to a substrate, by providing a substrate having bond pads on the die mount surface of the substrate, providing a die having interconnect sites at a die edge, positioning the die in relation to the substrate such that interconnect sites on the die are aligned with corresponding bond pads on the substrate, and dispensing an interconnect material dropwise (that is, by pulsed dispense of one or more droplets of the interconnect material), such that the interconnect material provides electrical continuity between the corresponding sites and bond pads. In some embodiments one or more additional die are mounted over the first die, and interconnected by dropwise deposition to form an electrically interconnected die stack electrically connected to the substrate.

In some embodiments a droplet of material is permitted, following a dispense pulse, to separate from the tool tip prior to movement of the tool. Various interconnect materials have various rheological properties in the uncured (or partially-cured) state, and rheological properties (such as viscosity, or thixotropy, for example) of particular materials may be exploited to provide droplets having controlled shapes. For example, a conductive polymer having higher viscosity and thixotropy in the uncured state can be shaped during deposition by moving the deposition tool immediately following a dispense pulse, to draw a “tail” of material in a selected direction to form an interconnect having a selected shape. Accordingly, in some embodiments, following a dispense pulse, the dispense tool is moved in a selected direction prior to separation of the droplet from the tool tip. A resulting interconnect may contact only the respective interconnect sites, and in some embodiments the resulting interconnect may take the form of an arc, for example.

In some embodiments each droplet is dispensed onto the target in a projectile manner; that is, the dispense tool is positioned such that the opening of the tip is at a distance from the target at the time the droplet is ejected from the tip of the tool. In a projectile dispense approach the dispense tool tip need not be held close to the target during deposition of the droplet and, advantageously therefore, the tip need not be manipulated in as carefully controlled a manner during formation of interconnects having more complicated geometries.

In some embodiments peripheral die pads constitute the interconnect sites on the die; in some embodiments interconnect terminals are attached to peripheral die pads and the interconnect terminals constitute the interconnect sites. In some embodiments the interconnect sites on the die include off-die interconnect terminals; in some embodiments the interconnect sites on the die include deposits of electrically conductive material (such as an electrically conductive polymer, for example); in some embodiments the interconnect sites on the die include electrically conductive traces connected to peripheral die pads and running to or near the die edge or around the die edge to the die sidewall.

In another general aspect the invention features a die assembly including a die mounted to a substrate or to another die, the substrate having bond pads, and the die having interconnect sites, in which corresponding interconnect sites are interconnected by pulsed dispense.

Pulsed dispense of electrically conductive material for electrical interconnection of die can be carried out more rapidly and at lower cost than continuous dispense.

The assemblies according to the invention can be used for building computers, telecommunications equipment, and consumer and industrial electronics devices.

### BRIEF DESCRIPTION OF THE DRAWINGS

FIG. 1 is a diagrammatic sketch in a perspective view showing a four-die stack assembly.

FIG. 2 is a diagrammatic sketch in a perspective view showing a four die stack as in FIG. 1, positioned for electrical interconnection on a substrate.

FIG. 3 is a diagrammatic sketch in a partial sectional view showing a four die stack, positioned for electrical interconnection on a substrate as in FIG. 2.

FIGS. 4A-4E are diagrammatic sketches in a partial sectional view generally as in FIG. 3, showing stages in a dot dispense process for electrical interconnection of a four die stack on a substrate according to an embodiment.

FIG. 4F is a diagrammatic sketch in a partial sectional view generally as in FIGs. 4A-4E, showing a stack of four die electrically interconnected with a substrate according to an embodiment.

FIGS. 5A, 5B are diagrammatic sketches in a partial sectional view showing a tip of a dot dispense tool.

FIGS. 6A and 6B are diagrammatic sketches in partial sectional view showing alternative dot dispense tool tip configurations according to other embodiments.

FIG. 7 is a diagrammatic sketch outlining apparatus, useful in making electrical interconnections, according to other embodiments.

FIG. 8A is a diagrammatic sketch in a partial sectional view showing a jet dispense tool tip suitable for projectile dot dispense.

FIGS. 8B and 8C are diagrammatic sketches in a partial sectional view generally as in FIG. 3, showing stages in a projectile dot dispense process for electrical interconnection of a four die stack on a substrate according to an embodiment.

FIGS. 9A and 9B are diagrammatic sketches in a partial sectional view, showing stages in a projectile dot dispense process for electrical interconnection of an offset eight die stack on a substrate according to an embodiment.

FIG. 10 is a diagrammatic sketch in a plan view showing an array of die mounted on a substrate array, ready for electrical interconnection according to another embodiment.

FIGS. 11A, 11B are diagrammatic sketches in a partial sectional view, showing a stack of three die electrically interconnected according to an embodiment.

FIGS. 12, 13A and 13B are diagrammatic sketches showing deposition profiles for droplets dispensed according to another embodiment.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs. Also for clarity of presentation certain features are not shown in the FIGs., where not necessary for an understanding of the invention.

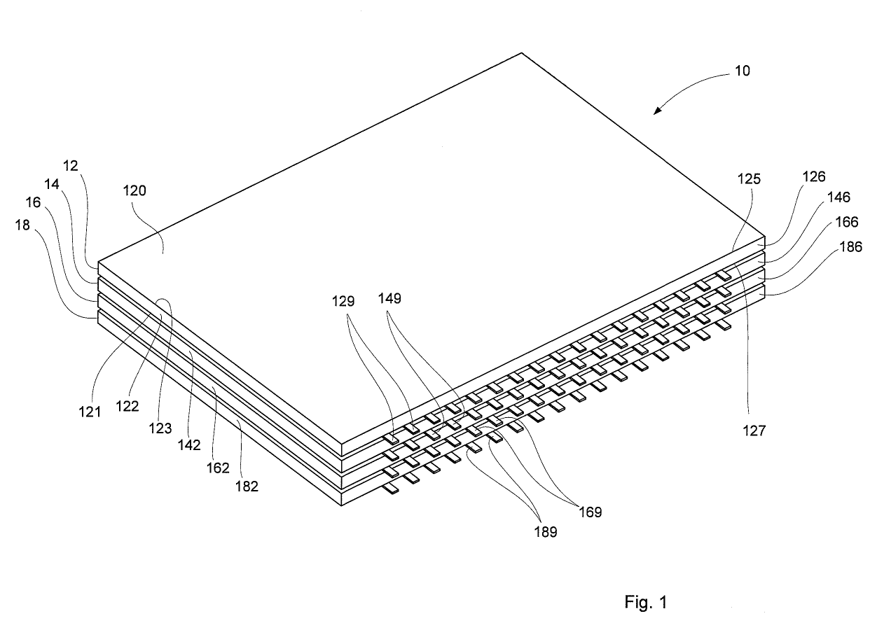

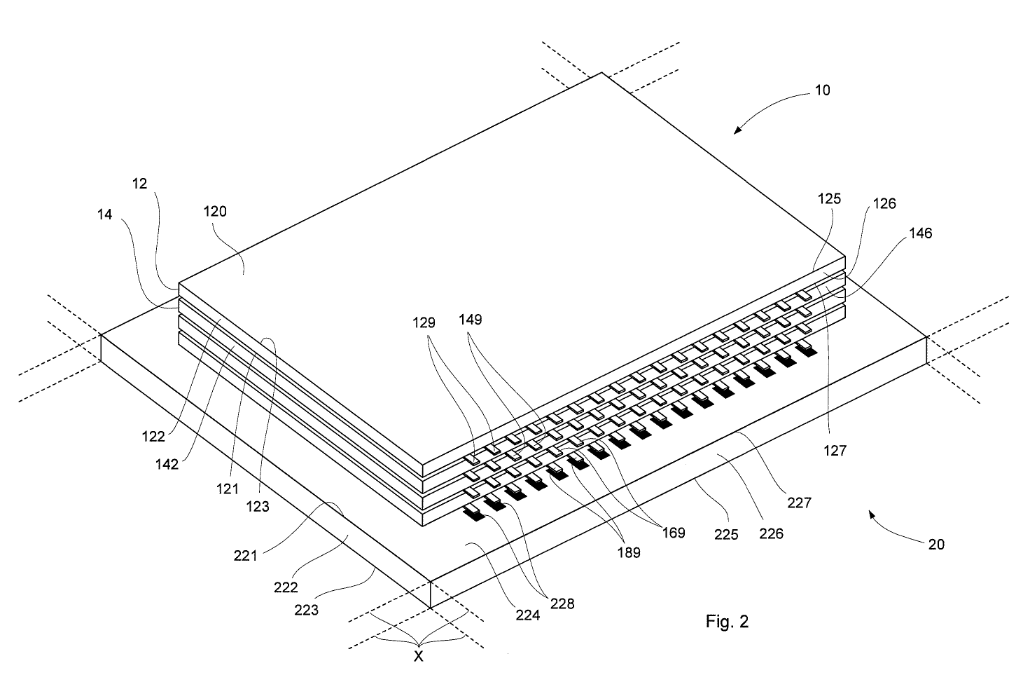

Turning now to FIG. 1, there is shown in a perspective view generally at 10 a stack of four semiconductor die 12, 14, 16, 18; and in FIG. 2, the die stack is shown mounted on a substrate, indicated generally at 20, ready for electrical interconnection. Each die has two larger generally parallel, generally rectangular (for example square) sides, and four sidewalls. One larger side may be referred to as the front side, and the other may be referred to as the back side. The circuitry of the die is situated at or near the die surface at the front side, and so the front side may be referred to as the active side of the die. In the view presented in FIGS. 1 and 2 the die are shown with the respective active sides facing away from view, toward the substrate 20, so that the back side 120 of die 12 is visible. Also visible in the view shown in FIGS. 1 and 2 are sidewalls 122, 126 of die 12, sidewalls 142, 146 of die 14, sidewalls 162, 166 of die 16, and sidewalls 182, 186 of die 18. Each die has front edges defined by the intersection of the sidewalls with the front side, and back edges defined by the intersection of the sidewalls with the back side; for example, back edges 125 and 123 are adjacent the sidewalls 126 and 122 on the back side of die 12, and front edges 127 and 121 are adjacent the sidewalls 126 and 122 on the front side of die 12. Interconnect terminals, e.g. 129, are bonded to interconnect pads at or near the edge 127 at the active side of die 12, interconnect terminals, e.g. 149, are bonded to interconnect pads at or near the edge at the active side of die 14, interconnect terminals, e.g. 169, are bonded to interconnect pads at or near the edge at the active side of die 16, and interconnect terminals, e.g. 189, are bonded to interconnect pads at or near the edge at the active side of die 18. The interconnect terminals project outward beyond the die edge in the embodiments shown in these FIGs. and, accordingly, they may be referred to as “off-die” interconnect terminals.

Referring particularly to FIG. 2, the substrate 20 has a die attach side 224, on which bond pads 228 are situated. A number of substrates 20 may be provided in a row or array, as suggested by the broken lines X; at some stage in the process, the substrates are separated, for example by sawing or punching. Each substrate has edges, of which edge 226 and 222 are visible in the view shown in FIG. 2; and margins of the substrate are adjacent the substrate edges; for example margins 227 and 221 are adjacent the edges 226 and 222 on the die attach side 224 of the substrate 20, and margins 225 and 223 are adjacent the edges 226 and 222 on the obverse side of the substrate 20.

In the embodiment shown by way of example in FIG. 2, the bond pads 228 are arranged in a row generally parallel to the margin 227, other pads (not visible in the FIG.) may be arranged in a row generally parallel to the opposite margin. The locations of the bond pads correspond to the locations of the interconnect terminals on the die (or die stack), when the die (or die stack) is mounted onto the substrate.

Other arrangements of bond pads are contemplated, according to the arrangements of pads on the particular die. In other embodiments the interconnect pads on the die may be situated along one die margin, or along three or all four margins; and the bond pads on the substrate in such embodiments are arranged correspondingly. Bond pads on the substrate may be arranged in two or more rows of pads along any one or more boundaries of the die footprint; and the bond pads may be interdigitated. In some embodiments, certain of the pads on a given die may not be connected to other die in the stack; for example, “chip select” or “chip enable” pads on a given die may be connected to underlying circuitry (on the substrate, for example), but not to other die. In such embodiments the terminals from such pads may connect to the bond pads in a second row along an edge of the die.

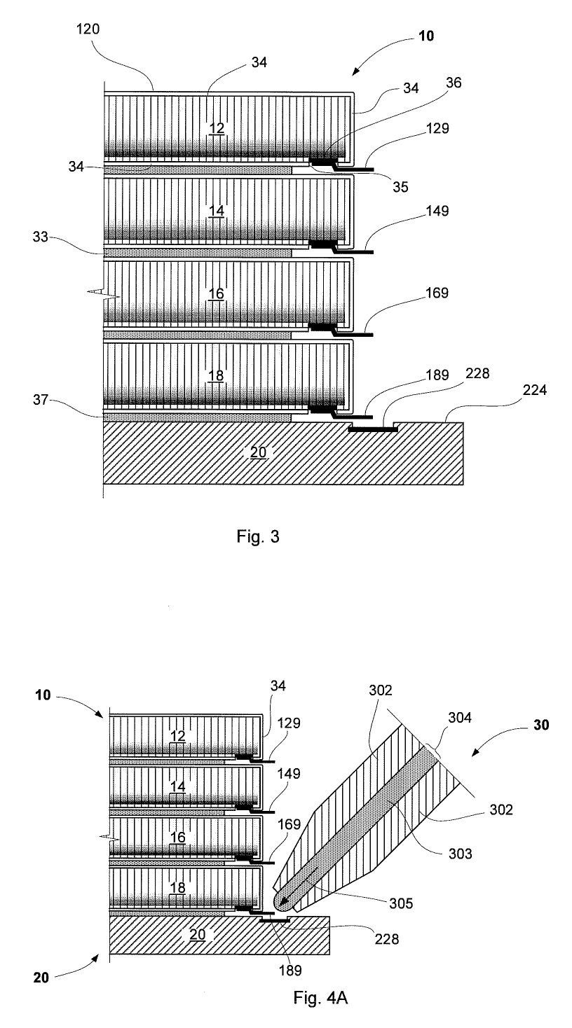

Referring now to FIG. 3, in a partial sectional view a stack 10 of four die 12, 14, 16, 18 is shown mounted on a substrate 20. In this example each die, e.g., die 12, is covered by an electrically insulative conformal coating 34; the coating covers the backside 120, the sidewalls, and the front side of the die, with openings (e.g. opening 35) in the coating over the die pads (e.g., pad 36), exposing an area of the pad for connection of an interconnect terminal (e.g., off-die terminal 129).

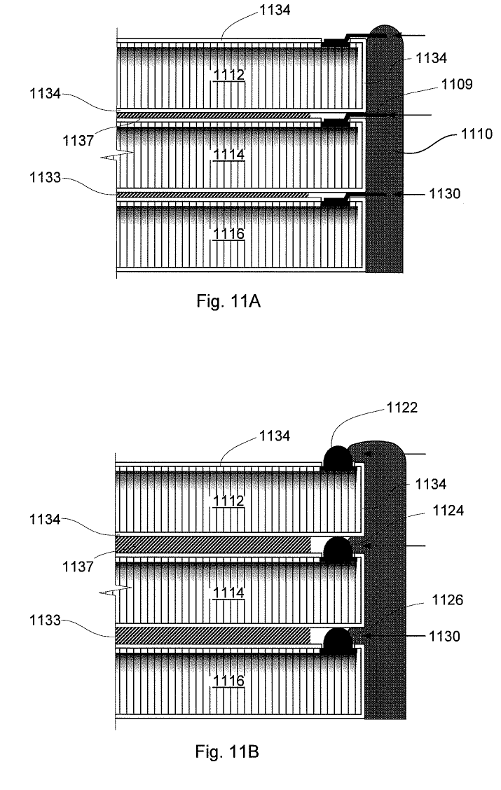

In other embodiments an electrically insulative conformal coating may be applied to the entire stack of die, rather than on each die before stacking; openings are made following the formation of the coating and prior to formation of the interconnects. And in other embodiments an off-die terminal may be omitted (see, for example, constructs shown in FIGS. 11B, 13A, 13B).

Adjacent die in the stack may optionally be mounted one upon the other using an adhesive. (The term “adjacent” with reference to die in a stack means the die are vertically adjacent; die may also be horizontally adjacent, for example in a wafer or in a die array or, in some configurations, on a common support.). In the example shown here, a film adhesive piece (such as a die attach film) is employed (e.g., 33 between adjacent die 14 and 16), and in this example the die attach film provides both adhesion and spacing between the die, to accommodate the off-die terminals.

In other embodiments the die attach film may be omitted, and spacing provided by other means. For instance, discrete spacers of a dielectric material may be arranged over a lower die, and the upper die may be set upon the spacers. Where the conformal dielectric coating is formed following stacking, and is formed by condensation of a polymer such as, for example, a parylene, the coating material condenses on all available surfaces, including on the die surfaces in the space provided by the spacers between the die, as described for example in U.S. Provisional Application No. 60/971,203, the pertinent portions of which are hereby incorporated herein by reference. The spacers have nominally the same height, to provide a standoff between overlying adjacent components in a range, for example, about 1 um to about 5 um. The spacers may be particles (such as, for example, small spheres of a dielectric material such as a glass or an organic polymer, for example) placed on the surface of the lower die; or, the spacers can be formed in situ, by printing or depositing discrete nubbins of a dielectric material such as an organic polymer on the lower die surface. The spacers can be formed of an adhesive, providing some affixation of the die in the stack, sufficient to hold the die in position during processing.

Bond pads 228 are arranged at the die mount surface 224 of the substrate 20. In the example shown, the die are arranged one over another with the respective interconnect terminals 129, 149, 169, 189 aligned vertically (that is, generally perpendicular to the front or back side of the die). And, in the example shown, the die stack 10 is mounted on the substrate with the respective interconnect terminals aligned at least partly over the respective bond pad 228.

The die stack may optionally be mounted on the substrate using an adhesive. In the example shown here, the die 18 adjacent the substrate 20 is affixed to the die mount side 224 of the substrate 20 using a film adhesive 37. As may be appreciated, a configuration as shown in FIG. 3 may be made by forming the die stack 10 and then mounting the die stack on a substrate 20; or, alternatively, it may be made in a build-up manner, by stacking the die serially on the substrate, that is by mounting die 18 on the substrate 20 (optionally using an adhesive 37), then mounting die 16 on die 18 (optionally using an adhesive 33), then mounting die 14 on die 16, etc.

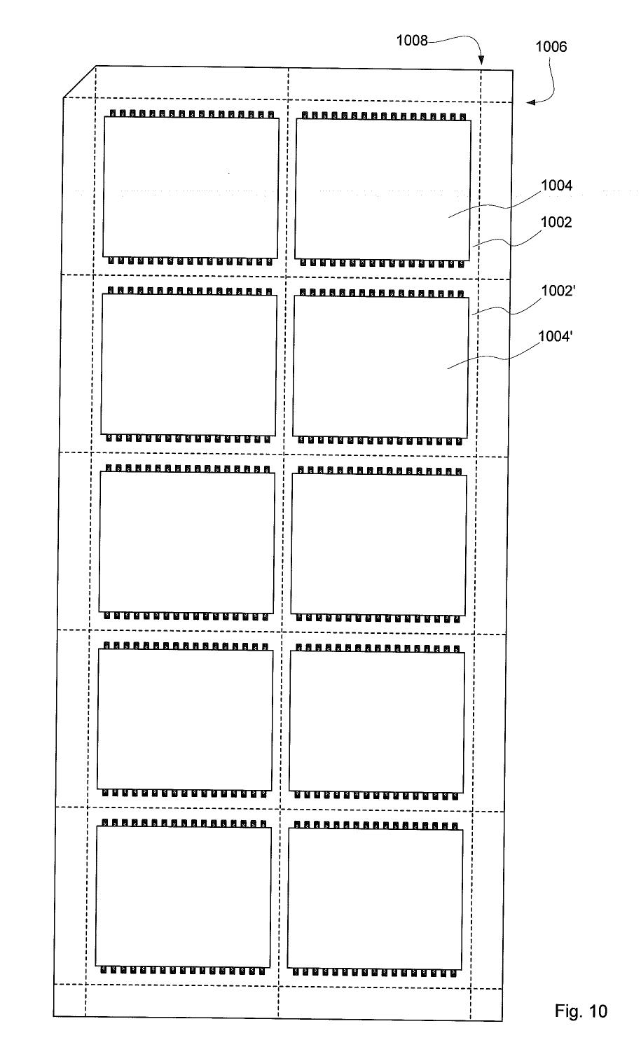

As noted above, FIG. 3 shows a partial sectional view of a die stack over a substrate, and a number of such substrates may be processed as a row or an array. FIG. 10 shows such an array of substrates, 1002, 1002′, e.g., with die stacks, 1004, 1004′, e.g., mounted and ready for interconnection. Broken lines 1006, 1008, e.g., indicate the lines along which the substrate array is severed to separate the individual assemblies following interconnection.

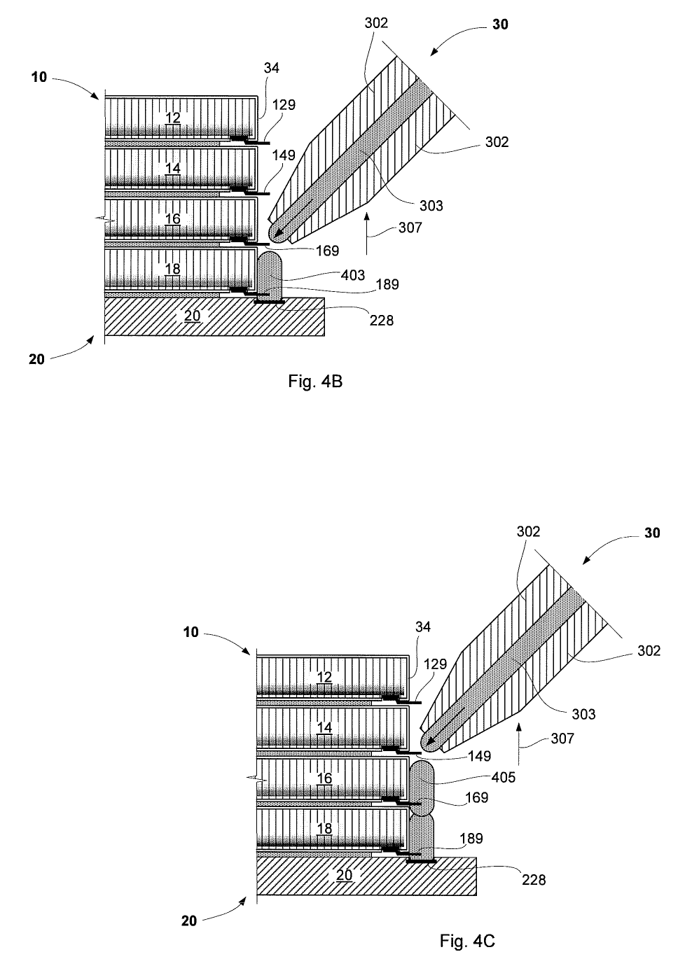

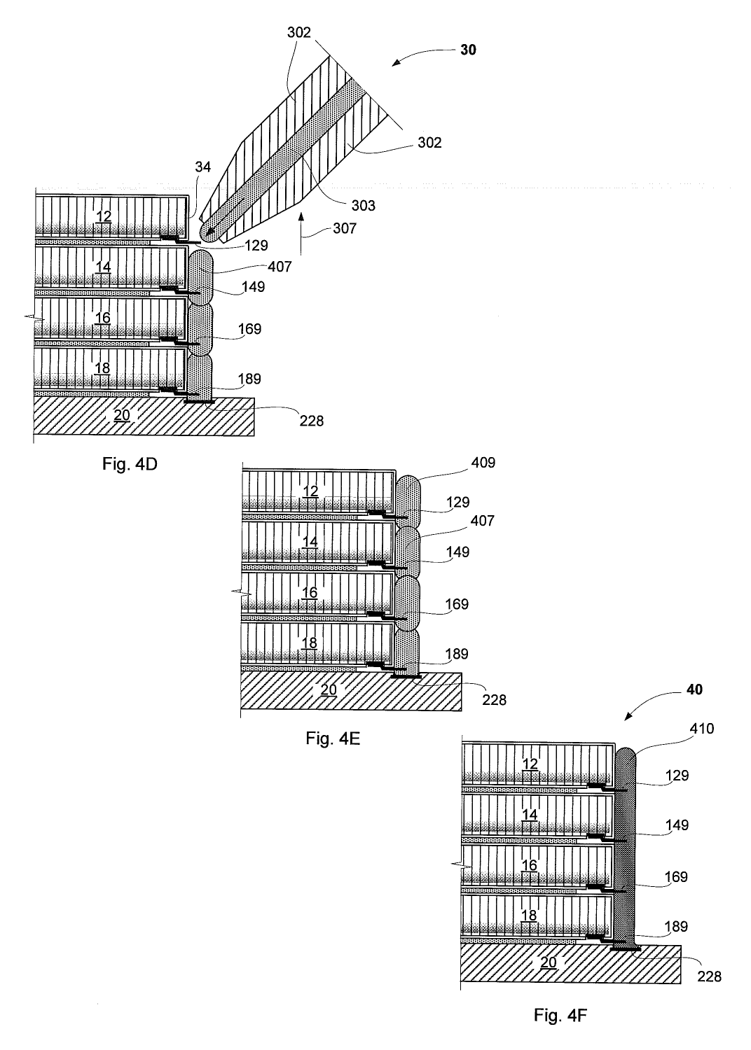

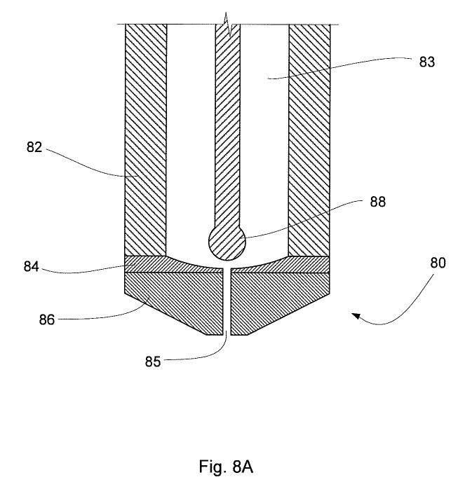

FIG. 4A shows, in a diagrammatic sectional view, a die stack 10 mounted on a substrate 20 generally as described with reference to FIG. 3, for example, and a dispense tool 30 positioned and ready for dispensing a first droplet of interconnect material in an interconnect process according to an embodiment of the invention. The dispense tool 30 includes a hollow tip having walls 302 defining a lumen 304. As is described below with reference to FIG. 7, the interconnect material is provided in an uncured state from a reservoir into the lumen as shown at 303 in FIG. 4A, and is dispensed from the tip of the dispenser as indicated by the arrow 305 onto the substrate and the die stack, generally as described below with reference to FIGS. 4B-4E.

The die assemblies shown in these Figures have off-die interconnects, as noted above (having tab bond or ribbon bond interconnect terminals). Interconnection by dropwise deposit of interconnect material may in other embodiments be made directly on die pads, such as on die having peripheral die pads without interconnect terminals; or on interconnect terminals formed as bumps or globs or knobs of electrically conductive material formed upon the peripheral pads and extending upward from the pads, and either extending or not extending toward the die edge (an example of the latter is illustrated for example in FIG. 11B). And, interconnection by dropwise deposit of interconnect material may in other embodiments be made on interconnect terminals constituting electrically conductive traces not projecting beyond the die edge, including traces connected with the die pads and running to the die edge, or around the die edge onto the die sidewall.

The interconnect material is selected or formulated to have suitable physical characteristics (thixotropy, rheological characteristics, viscosity, etc.) for deposition. Particularly, the material must be sufficiently flowable to be expelled or ejected from the tool tip in suitably sized droplets. Preferably the material as deposited is sufficiently deformable in the uncured (or partly cured) state to permit it to conform at least to some extent to the target upon which it is deposited, to facilitate good electrical contact where required, including contact with previously deposited droplets that form a part of an interconnect. Also preferably the material as deposited is sufficiently stiff so as not to flow away from the intended site.

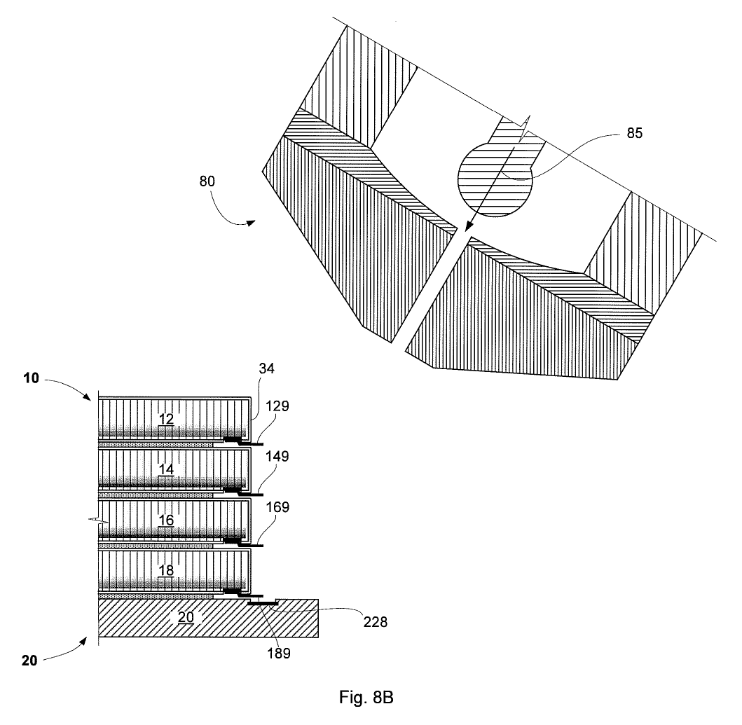

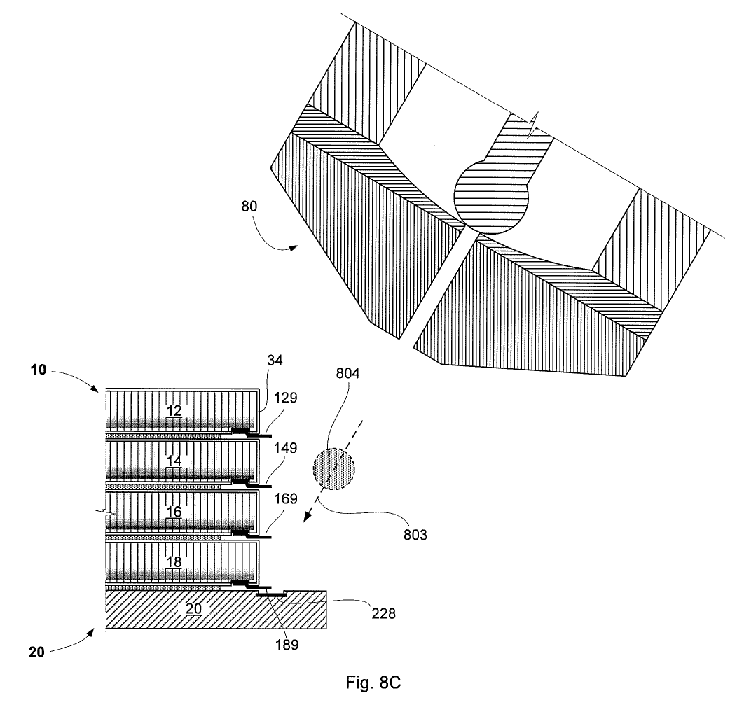

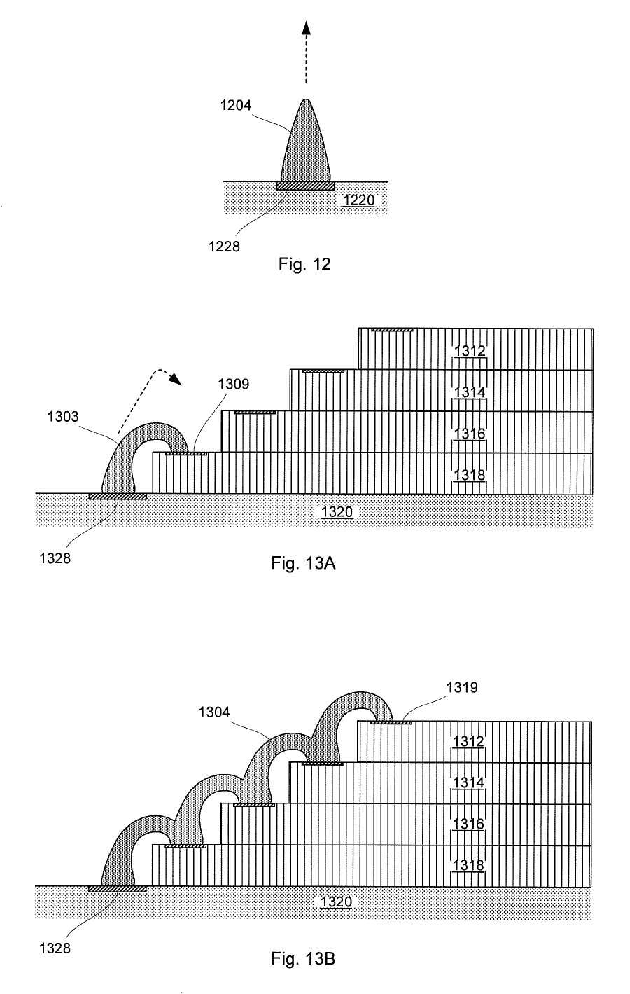

The droplets of interconnect material are shown in the FIGs. as having the shape of spheres or lozenges, but in practice the material will not have such a shape, either as deposited (as shown for example in FIGS. 4B-4E) or as ejected from the tool (as discussed below with reference to FIGS. 8B, 8C). As noted below with reference to FIGS. 12, 13A, 13B, rheologic characteristics of the interconnect material in the uncured state may be exploited to provide deposits having a variety of desired shapes.

The interconnect material may include, for example, a matrix containing an electrically conductive filler; the matrix may be a curable or settable material, and the electrically conductive fill may be in particulate form, for example, such that when the matrix sets or is cured, the material is itself electrically conductive. In some embodiments the material is a conductive epoxy such as a silver filled epoxy; for example, a filled epoxy having 60-90% (more usually 80-85%) silver may be suitable. The epoxy is cured following dispensing, resulting in some embodiments in a fusion of the series of dots into a continuous interconnect strand.

The pulsed dispense may alternatively or additionally be employed to deposit electrically nonconductive materials having similar physical properties (rheology, thixotropy, viscosity, and the like). For example, an electrically nonconductive line may be formed over a conductive trace, for example to provide electrical insulation for subsequent deposition of an overlying conductive trace.

FIG. 4B shows a stage in an interconnect process at which a first droplet of interconnect material has been deposited, and the dispense tool 30 has been moved upward, as indicated by arrow 307, into position for deposition of the next droplet. At this stage the first droplet 403 of interconnect material contacts the bond pad 228 and a first interconnect terminal 189. The droplet is insulated from the semiconductor material of the die 18 (and other die in the stack) by the electrically insulative conformal coating covering the die surfaces and edges.

FIG. 4C shows a subsequent stage in an interconnect process at which a second droplet of interconnect material has been deposited, and the dispense tool 30 has again been moved upward, as indicated by arrow 307, into position for deposition of the next droplet. At this stage the second droplet 405 of interconnect material contacts the first droplet 403 and a second interconnect terminal 169. The droplet is insulated from the semiconductor material of the die 16 (and other die in the stack) by the electrically insulative conformal coating covering the die surfaces and edges.

FIG. 4D shows a subsequent stage in an interconnect process at which a third droplet 407 of interconnect material has been deposited, and the dispense tool 30 has again been moved upward, as indicated by arrow 303, into position for deposition of the next droplet. At this stage the third droplet 407 of interconnect material contacts the second droplet 405 and a third interconnect terminal 149. The droplet is insulated from the semiconductor material of the die 14 (and other die in the stack) by the electrically insulative conformal coating covering the die surfaces and edges.

FIG. 4E shows a subsequent stage in an interconnect process at which a fourth droplet 409 of interconnect material has been deposited, and the dispense tool 30 has been withdrawn, as the deposition of the interconnect material is complete for this interconnect. At this stage the fourth droplet 409 of interconnect material contacts the third droplet 407 and a fourth interconnect terminal 129. The droplet is insulated from the semiconductor material of the die 12 (and other die in the stack) by the electrically insulative conformal coating covering the die surfaces and edges. The interconnect may now be partially or fully cured to complete the interconnection.

FIG. 4F shows generally at 40 a stacked die assembly following cure of the interconnect. The assembly in this example has a stack of four die mounted on a substrate, generally as described with reference to FIG. 4A, in which the die are electrically interconnected to one another, and to the substrate circuitry (z-interconnection) by the “vertical” interconnect 410; that is the interconnect 410 provides electrical continuity between the interconnect terminals 129, 149, 169, 189 and the bond pad 228 on the substrate 20.

The interconnects may be formed in any of a variety of shapes, and no particular shape is required, so long as the desired electrical continuity is established by each interconnect.

In the embodiments shown in the Figures, the droplets as deposited are large enough to make contact with underlying circuitry or with a preceding droplet as well as with an interconnect terminal. Alternatively, the droplets may be smaller, for example, so that more than one droplet is required to establish electrical continuity between adjacent features in the stack. Or, alternatively, the droplets may be larger, for example, so that, depending upon the size (e.g., height) of the interconnection, a single droplet may suffice; or, where more than one droplet may be required to effect a complete interconnect, a given droplet may be employed to connect features on adjacent die in the stack. A droplet may have a mass in the range about 4 mg to about 12 mg, for example, and a droplet may have a nominal diameter as small as about 20-30 um, usually about 75 um, and as large as about 600 um. As may be appreciated, where larger droplets are dispensed, fewer droplets need be deposited to complete a particular interconnect; on the other hand, smaller droplets may be required to form narrower interconnects.

The size of the droplet is determined by the mass of material dispensed in each pulse; that is, the tool dispenses a desired mass of the material toward the target in each pulse, and the dispense pulse in the tool is substantially or entirely completed prior to moving the tool toward a subsequent target. In embodiments where droplets are deposited discretely, whatever their size and shape, and however many droplets may be deposited to form a particular interconnect, deposition of each droplet is substantially completed and the droplet mass separates from the tool tip before the tool is moved for deposition of a subsequent droplet in the same or on a different interconnect. In other embodiments a portion of the droplet mass may remain in contact with tool for a time following completion of the pulse, and the tool may be moved before separation is complete; in such embodiments the shape of the deposited mass may be determined to some degree by the direction and rate of movement of the tool as well as the rheologic properties of the material. An example is described below with reference to FIGS. 12, 13A, 13B.

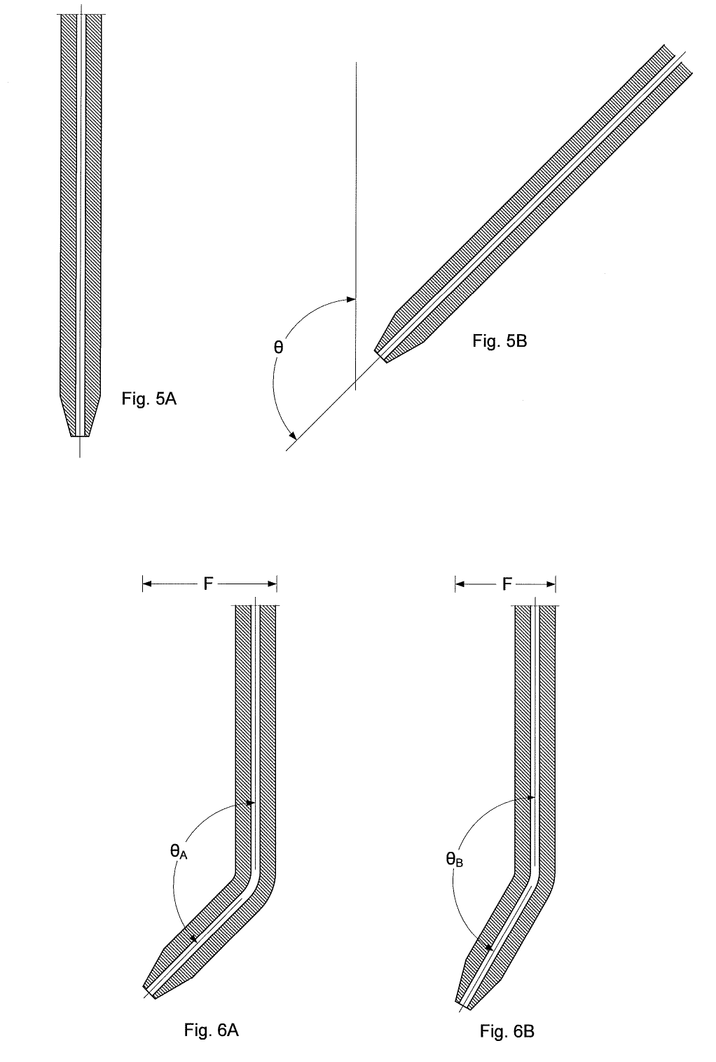

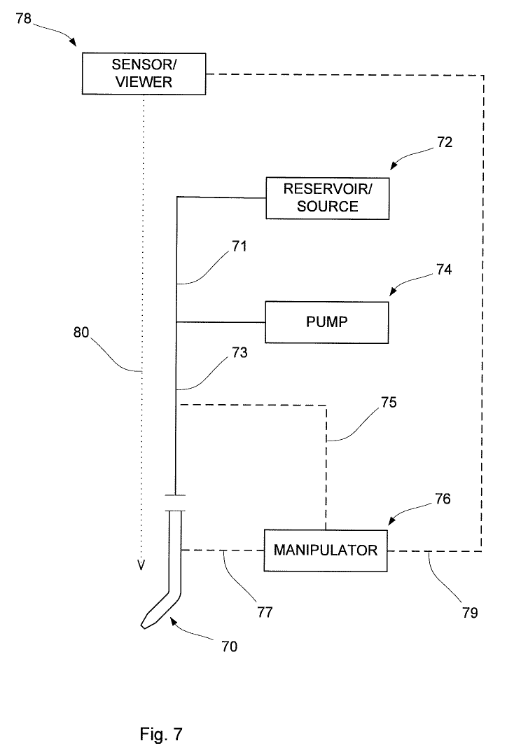

FIGS. 5A, 5B shows a dispense tool tip in a straight configuration, oriented with the lumen axis pointing vertically (in FIG. 5A) or in a direction at an angle θ with respect to vertical (in FIG. 5B). For purposes of orientation of the tool tip the die are presumed to lie parallel to a substantially horizontal plane beneath the tool. The angle θ may range from nearly vertical to nearly horizontal. As a practical matter, where the die (and the row of interconnect terminals associated with the respective die) are vertically aligned, as shown for example in FIGS. 3, 8B, 11A, 11B, the angle θ is preferably at least slightly less than 180°, so that the tool tip “sees” the sidewall of the die being targeted; and the angle θ is preferably at least slightly greater than 90°, so that the tool tip “sees” the front side of the die bearing the interconnect sites. This ensures sufficient “wetting” of the surfaces by the deposited interconnect material. The angle θ may in some embodiments be 135° (45° from horizontal, that is 45° from the plane of the substrate or of the die back side), for example. FIGS. 6A and 6B show dispense tool tips having a bent configuration, so that axis of the tip body is vertically oriented, and the tool is curved or bent so that the lumen axis of an exit part of the tip is oriented at an angle (e.g., θA in FIG. 6A, and θB in FIG. 6B). As the Figures illustrate, a bent tool tip configuration can reduce the space occupied by the tool adjacent the tip opening, that is, adjacent the face of the die stack being treated; and a greater angle θ (e.g., θB greater than θA) provides for a narrower footprint (e.g., F_{B} narrower than F_{A}). This may be particularly advantageous in forming interconnects on die stacks in an array, as illustrated in FIG. 10.

Preferably, apparatus for forming the interconnections is at least partially automated. Referring to FIG. 7, the apparatus may include, in addition to the dispense tool tip 70, a reservoir or source 72 of interconnect material, and a pump 74 for propelling the interconnect material through the tool tip 70. The pump may include for example a piston-and-cylinder device, in which the cylinder contains interconnect material, and a driver moves the piston in the cylinder to propel the interconnect material by way of a tube 73 to and through the lumen of the tool tip 70. The cylinder may itself constitute the reservoir; or, alternatively, the reservoir or source may be connected to the pump by way of a tube 71, to keep the pump (for example the cylinder) supplied with material. The driver operates to move the piston in a stepwise or pulsing fashion, each step or pulse being metered to provide a specified mass of material at the tool tip. For further automation, a controlled mechanical manipulator may be coupled to the tool tip (and, optionally, to the tubing connecting the pump to the tool tip, or to the pump itself, or to the pump and reservoir), to move and to position the tool tip in relation to the target on the die stack face. The controlled manipulator preferably is capable of moving and positioning the tool tip in an X-Y plane (generally parallel to the plane of the die back side) and in a Z direction (perpendicular to the die back side and generally parallel to the die stack face). The apparatus may further include a viewer or position sensor 78, which may for example include an optical device having a line of sight along which an image of the tool tip 70 and its surroundings may be viewed, as indicated at 80. The operator of the device may employ the viewer/sensor either to position the tool tip for each interconnection; or, the movement and positioning of the tool tip may be entirely automated, and the operator of the device may employ the viewer to monitor the progress, or to make an initial setup.

Rather than a cylinder-and-piston or cylinder-and-plunger approach as described above with reference to FIGS. 8A, 8B, 8C, pulses may alternatively be effected by a mechanism analogous to those used in inkjet or bubblejet printers. Particularly, for example, the mass of material in the tool may be displaced by a set amount by operation of a piezoelectric device, or by temporary formation of a bubble, for example by a thermal burst. Such a mechanism may be more appropriately employed for materials having lower viscosity and thixotropy, such as for example so-called electrically conductive inks.

In the examples shown in FIGS. 4A through 4E, the tool tip opening is positioned close to the target, so that each droplet contacts the target as it is expelled from the tip. In this approach, each droplet may be severed from the mass of material in the tool tip (or separated from the tool tip) by withdrawal of the mass of material into the lumen of the tip, and/or by surface tension at the target drawing the droplet away from the tool tip and the mass of material in the tip lumen, and/or by the movement of the tool tip upward or away from the droplet, after it is expelled.

In an alternative approach, the tool tip opening is positioned at some distance from the target, and the droplet is ejected from the tip so that it separates from the mass of material in the tool tip and passes as a projectile to the target. A suitable jet dispense tool tip is illustrated by way of example in FIG. 8A. The tool in this example includes a barrel having walls 82 enclosing a chamber 83 containing the interconnect material to be deposited. The barrel is joined in a sealed relation to a seat 84, and a nozzle 86 having a narrow exit 85 is joined in a sealed relation to the seat 84. A piston 88 is axially arranged in the chamber, and coupled to an actuator configured to move the piston forcibly in an axial direction toward the exit into contact with the seat. Movement of the piston in this manner results in ejection of a quantity of the interconnect material out from the chamber through the exit.

Projectile dropwise dispense is illustrated in FIGS. 8B and 8C. FIG. 8B shows the tool tip 80 positioned so that the opening is at some distance from the target. The apparatus is set to forcibly move the piston toward the exit, as indicated by the arrow 85 to eject a quantity of material rapidly from the tip, so that a droplet of material is forcibly ejected from the tip opening as shown in FIG. 8C and traverses the distance to the target along a line 803 as a projectile droplet 804. As with the contact droplet dispense illustrated with reference to FIGS. 4A-4E, the size (mass or volume) of the ejected droplet here is determined by the volume displaced by each advance of the piston; the projectile path of the droplet may be more or less direct (more or less in a straight line) depending upon the force (rapidity) of the displacement. The shape of the droplet is shown as spherical in the diagrammatic illustration; in fact, it may have a roughly teardrop shape, or it may have an irregular shape, depending among other factors on the rheologic properties (for example, viscosity, thixotropy) of the material. Following ejection of a droplet 804, the tool tip is moved to position it for projectile deposition of a subsequent drop.

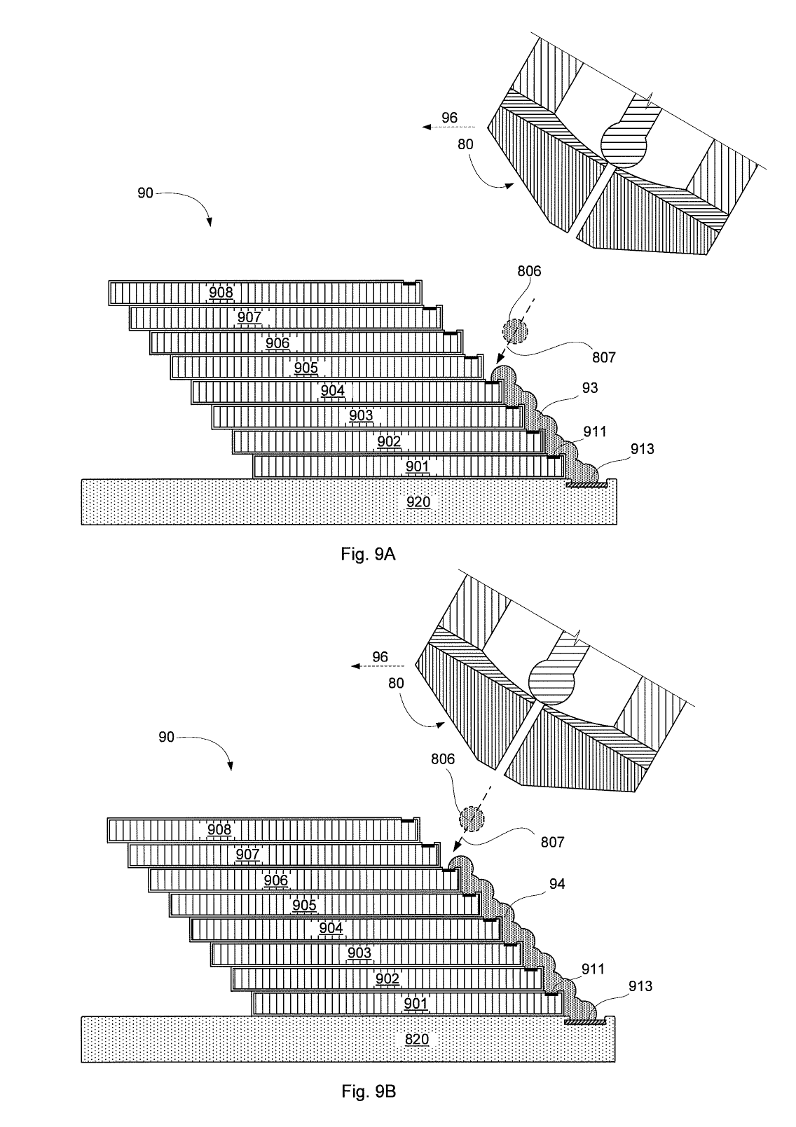

In the Figures referred to above, the die are provided with off-die interconnect terminals, and the die are stacked so that the die edge adjacent the die pads in each overlying die is directly aligned with the edge of the underlying die. In such embodiments the die sidewalls in the stack are oriented in a substantially coplanar manner, and the stack presents a generally planar stack face, generally perpendicular to the die front sides. In other embodiments successive die in the stack may be offset, as shown for example in FIGS. 9A, 9B. Where the die are offset, they may be covered with an electrically insulative coating, such as a conformal coating of an insulative polymer (for example, a parylene), and stacked one directly upon one another, offset along the edges adjacent the die pads to expose at least a portion of the area of the die pads on each underlying die for interconnection. Pulsed dispense—and particularly projectile dropwise dispense—of interconnect material may be particularly suitable for interconnection of such a die stack configuration. Referring to FIG. 9A, a stack of successive die 901, 902, 903, 904, 905, 906, 907, 908, are mounted on a support 920. The support has bond pads 913 connected to circuitry in, and situated in a stack mount side of, the support, in an arrangement suitable for alignment with peripheral die pads, e.g., die pad 911. FIGS. 9A and 9B show stages in a process for projectile droplet dispense of interconnect material. The tool 80 is shown in each of FIGS. 9A, 9B, at a stage at which a projectile droplet 806 has been ejected along a trajectory 807 toward a target on the stack assembly. Between the stages shown in these Figures, the tool has been advanced horizontally, stepwise following each droplet dispense, as indicated by the arrows 96, to form the track of interconnection material 93, 94. The tool may in such an approach be advanced in a direction (or directions) different from the horizontal direction shown here. As will be appreciated, use of a contact pulsed dispense (as compared with the projectile dispense shown here) to form interconnections on offset die stacks would require many controlled maneuvers of the tool tip, to maintain proximity with the target.

As shown in FIG. 11A, the die 1112, 1114, 1116 in the stack may be oriented with the active side of the die facing away from the substrate (below the stack; not shown in the FiG.). In this orientation the interconnect terminals are situated above each die, and are laterally accessible (as indicated by arrows 1130) for interconnection by the interconnect trace 1110. The die in this example are each covered by a conformal dielectric coating 1134 through which openings have been made to expose the interconnect pads, and the die are separated by spacers 1133. The interconnection 1110 is formed substantially as described with reference to FIGS. 4B-4F.

FIG. 11B shows an example of an interconnect die stack in which the die have no off-die interconnects. Instead, in this example each die pad is provided with a bump or knob or glob 1122, 1124, 1126 of electrically conductive material which extends above the pad. Vertically adjacent die are separated by a spacer 1133, to accommodate the height of the glob 1122. Although the glob does not extend toward the die edge in this embodiment, it does not constitute an off-die terminal. Nevertheless, the globs are laterally accessible (as indicated by arrows 1130) for interconnection by incursion of material from the interconnect mass between the die. Any of various conductive materials may be suitable as the globs or knobs on the interconnect terminals. The knob may be a metal bump, for example, such as a stud bump formed of gold using a wire bonding tool; or, the knob may be a solder bump, which may be formed as a deposit of a solder paste, for example, which may be formed by printing or dispensing; or, the knob may be metal, formed for example in a plating process; or, the knob may be a deposit of an electrically conductive polymer. Where the knob is a glob of an electrically conductive polymer, the material can include any of the various materials that are suitable for the interconnect trace material itself, and can be formed by, for example, any of the techniques described for forming the interconnect traces, as described above. The glob or knob may have a height in a range, for example, about 25 um-about 50 um; is required only that, given the rheologic properties of the particular interconnect material, the space between the die and the height of the knob or glob is sufficiently great to permit the interconnect material is able to ooze into the space between the die, and make good contact with the glob or knob.

In other embodiments, the interconnect terminals may be configured so that they are directly accessible at the stack face, as shown for example in U.S. Application Atty Docket No. 1041-2, referenced above and incorporated by reference herein.

As noted above, Theological properties (such as viscosity, or thixotropy, for example) of particular materials may be exploited to provide droplets having controlled shapes. Particularly, for some materials a portion of the droplet mass may remain in contact with tool for a time following completion of the pulse, and the tool may be moved before separation is complete. A conductive polymer material having higher viscosity and thixotropy in the uncured state can be shaped during deposition by moving the deposition tool immediately following a dispense pulse, to draw a “tail” of material in a selected direction to form an interconnect having a selected shape. As a result, the shape of the deposited mass may be determined to some degree by the direction and rate of movement of the tool as well as the rheologic properties of the material.

Referring to FIG. 12, for example, a droplet 1204 is shown attached to an electrical contact 1228 on a support 1220 (such as a pad on a die, or a bond pad on a substrate). In the example shown, the tool tip (not shown in this FIG.) was directed toward the contact 1228 target, and a pulse dispense was imposed on the material in the tool to force a mass of material onto the target. Then, while the mass of material was still in contact with the tool tip, the tool was moved perpendicularly away from the target (as indicated by the broken arrow pointing upward in the FIG.) to draw a “tail” of material upward. Eventually the droplet mass separated from the tool tip, and the resulting droplet 1204 has a generally conical shape. Materials suitable for forming shaped droplets include electrically conductive epoxies having, in the uncured state, a viscosity about 30,000 cps or greater and a thixotropic index about 6.5 or greater. As will be appreciated, the viscosity and thixotropy must not be too high, or else the material may be unworkable, or it may not make good contact with the interconnect terminals.

A series of such roughly conical free standing droplets can be formed one over another adjacent a die stack face, providing a column of material contacting the interconnect terminals. Such a columnar configuration may be particularly useful where there is a significant space between vertically adjacent die, so that the interconnect trace must vertically traverse the space without lateral support. This may be presented in die stacks having a staggered arrangement of die (that is, where the space between the die to be connected approximate (or somewhat exceed) the thickness of an interposed offset die; or in die stacks having elongated stacked die each oriented 90° to the die below. Such arrangements are described in U.S. Application Atty Docket No. VCIX 1041-2, referenced above and incorporated by reference herein.

The tool can be moved in other directions than vertically away from the target, and various useful droplet shapes can result. Referring for example to FIGS. 13A, 13B, a stack of offset die 1312, 1314, 1315, 1316, is shown mounted on a substrate 1320 having an electrical connection site (such as a bond pad) 1328 in the stack mount side. All the die in this example have peripheral pads, e.g., 1309, 1319, arranged in an interconnect margin along an edge of the die. Each die in the stack is displaced with respect to the die beneath, to expose at least a portion of the area of the pads (exposing the entirety of the pads in the example shown). A first interconnect droplet 1303 is shown connecting the die pad 1309 on the first die 1318 to the bond pad 1328 in the substrate 1320. To form the droplet, the tool was directed toward the first target bond pad 1328, and a pulse dispense was imposed on the material in the tool to force a mass of material onto the first target. Then, while the mass of material was still in contact with the tool tip, the tool was moved, first upwardly and laterally away from the first target and then downwardly and laterally toward the second target die pad 1309 (as indicated by the broken arrow) to draw a “tail” of material in an arc toward the second pad. Then second and subsequent droplets were similar formed: the first target for the second droplet is the die pad 1309 on the first die 1318, and the second target for the second droplet is the die pad on the next die 1316 in the stack. This is repeated until all the die have been interconnected, with a result as shown in FIG. 13B. Because each droplet in this embodiment contacts only the respective interconnect sites, and does not contact (for example) the die edge or the die sidewall, it is not necessary here to electrically insulate the die edge or die sidewall surfaces (although the interfaces between vertically adjacent die in the stack may require insulation, not shown in the FIGs.).

Other embodiments are within the scope of the invention.

We claim:

1. A method for forming an electrical interconnect, comprising depositing a first droplet of an interconnect material at a first target, and depositing a second droplet of an interconnect material on a second target, the first and second droplets contacting one another to provide electrical continuity between the first and second targets.

2. The method of claim 1 wherein the second droplet as deposited contacts the first droplet.

3. The method of claim 1 wherein the second droplet is allowed to contact the first droplet subsequent to depositing the droplets.

4. The method of claim 1 wherein a subsequent treatment contacts the second droplet with the first droplet.

5. The method of claim 1 wherein one of the first and second targets includes an electrical feature on a die.

6. The method of claim 5 wherein each of the first and second targets includes an electrical feature on a die.

7. The method of claim 5 wherein the electrical feature comprises an interconnect terminal.

8. The method of claim 5 wherein the electrical feature comprises an interconnect pad.

9. The method of claim 1 wherein the first target comprises an electrical feature on underlying circuitry.

10. The method of claim 9 wherein the first target comprises a bond pad.

11. The method of claim 9 wherein the first target comprises an electrical feature on a substrate.

12. The method of claim 9 wherein the first target comprises an electrical feature on a printed circuit board.

13. The method of claim 1 wherein the first target comprises both an electrical feature on a die and an electrical feature on underlying circuitry.

14. The method of claim 1 wherein the interconnect material comprises a curable material.

15. The method of claim 1 wherein depositing the interconnect material comprises depositing a curable interconnect material in an uncured or partially cured state.

16. The method of claim 15, further comprising partially or additionally curing the interconnect material.

17. The method of claim 15, further comprising fully curing the interconnect material.

18. The method of claim 1 wherein the interconnect material comprises an electrically conductive polymer.

19. The method of claim 18 wherein the electrically conductive polymer comprises a polymer filled with conductive material in particle form.

20. The method of claim 19 wherein the electrically conductive polymer comprises a metal-filled polymer.

21. The method of claim 1 wherein the interconnect material comprises a partially-curable polymer, and wherein the method further comprises curing the polymer in stages.

22. The method of claim 1 wherein the interconnect material comprises a metal filled epoxy.

23. The method of claim 1 wherein the interconnect material comprises a metal filled thermosetting polymer.

24. The method of claim 1 wherein the interconnect material comprises a metal filled thermoplastic polymer.

25. The method of claim 1 wherein the interconnect material comprises an electrically conductive ink.

26. A method for electrically interconnecting at least two die including a first die and a second die, the first and second die each having interconnect sites at or near a die edge, comprising positioning the die in relation to the one another such that corresponding sites to be connected are aligned, and dispensing an interconnect material dropwise, such that the interconnect material provides electrical continuity between the corresponding sites.

27. The method of claim 26, further comprising mounting at least one additional die over the first two die, and interconnecting the additional die by dropwise deposition to form an electrically interconnected stacked die assembly.

28. The method of claim 26, further comprising mounting the interconnected stacked die assembly onto a support, and electrically connecting the assembly to underlying circuitry in the support.

29. The method of claim 28 wherein the support comprises a substrate.

30. The method of claim 28 wherein the support comprises a leadframe.

31. The method of claim 28 wherein the support comprises a printed circuit board.

32. The method of claim 26 wherein the die are stacked so that the die edges overlie one another so that the stack face is generally planar and generally perpendicular to the die front side.

33. The method of claim 26 wherein the die are stacked so that successive die in the stack are offset so that the die edges adjacent the interconnect sites present a stairstep configuration.

34. A method for electrically interconnecting a die to a substrate, comprising providing a substrate having bond pads on a die mount surface thereof, providing a first die having interconnect sites at an edge thereof, positioning the first die in relation to the substrate such that interconnect sites on the first die are aligned with corresponding bond pads on the substrate, and dispensing an interconnect material dropwise such that the interconnect material provides electrical continuity between the corresponding sites and bond pads.

35. The method of claim 34 further comprising mounting at least one additional die over the first die, and interconnecting the additional die by dispensing an interconnect material dropwise to form an electrically interconnected die stack electrically connected to the substrate.

36. The method of claim 34 wherein peripheral die pads constitute the interconnect sites on the die.

37. The method of claim 34 wherein interconnect terminals are attached to peripheral die pads and the interconnect terminals constitute the interconnect sites.

38. The method of claim 34 wherein the interconnect sites on the die comprise off-die interconnect terminals.

39. The method of claim 34 wherein the interconnect sites on the die comprise deposits of electrically conductive material.

40. The method of claim 34 wherein the interconnect sites on the die include electrically conductive traces connected to peripheral die pads and running to or near the die edge or around the die edge to a die sidewall.

41. The method of claim 1 wherein each droplet is dispensed onto the target in a projectile manner.

42. A method for forming an electrical interconnect between electrical interconnect sites, comprising pulse dispensing an interconnect material, the interconnect material making electrical contact with at least one said electrical interconnect site.

43. The method of claim 42, the electrical interconnect site comprising an interconnection site on a die.

44. The method of claim 43, the electrical interconnect site comprising an interconnection site on a support.

45. The method of claim 44, the electrical interconnect site comprising an interconnection site on a leadframe.

46. The method of claim 44, the electrical interconnect site comprising an interconnection site on a package substrate.

47. The method of claim 44, the electrical interconnect site comprising an interconnection site on a printed circuit board.
